(19) United States
(12) Patent Application Publication
(10) Pub. No.: US 2026/0303091 A1
(43) Pub. Date: Oct. 1, 2026

(54) GATE DRIVER CIRCUIT, THREE-PHASE GATE DRIVER, AND SWITCHING CIRCUIT

(71) Applicant: ROHM CO., LTD., Kyoto-shi (JP)

(72) Inventor: Hisashi SUGIE, Kyoto-shi (JP)

(21) Appl. No.: 19/634,205

(22) Filed: Mar. 31, 2026

(30) Foreign Application Priority Data
Mar. 31, 2025 (JP) 2025-059368
Feb. 5, 2026 (JP) 2026-018069

(51) Int. Cl. H03K 17/687; H02M 1/088; H02M 3/07

(52) U.S. Cl. CPC H03K 17/6871; H02M 1/088; H02M 3/07; H03K 2217/0063

(57) ABSTRACT

A gate driver circuit includes: a high-side driver that drives a high-side transistor; a charge pump line to which a charge pump voltage higher than an input voltage of the high-side transistor and generated by a charge pump circuit is supplied; a current source circuit that is structured to be able to supply a constant current from the charge pump line to a bootstrap capacitor for driving the high-side transistor; and a current control circuit that controls on/off of supply of the constant current to the bootstrap capacitor by the current source circuit. The charge pump circuit may not have an output capacitor.

### CROSS REFERENCE TO RELATED APPLICATIONS

The present invention claims priority under 35 U.S.C. § 119 to Japanese Application No. 2025-059368, filed Mar. 31, 2025, and Japanese Application No. 2026-018069, filed Feb. 5, 2026, the entire contents of which being incorporated herein by reference.

### BACKGROUND

### 1. Technical Field

The present disclosure relates to a gate driver circuit, a three-phase gate driver, and a switching circuit.

### 2. Description of the Related Art

Conventionally, a transistor and a gate driver circuit for driving the transistor are used in various applications such as a DC/DC converter and a motor drive device.

When a high-side transistor including an N-channel metal oxide semiconductor (MOS) transistor is driven, a bootstrap circuit may be used (see Japanese Patent Application (Laid Open) No. 2024-160804). The bootstrap circuit generates a bootstrap voltage higher than an input voltage of the high-side transistor. The high-side transistor is driven using the bootstrap voltage.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram of an electronic device according to a first embodiment;

FIG. 2 is a circuit diagram of a charge pump circuit according to the first embodiment;

FIG. 3 is a circuit diagram of a current source circuit according to the first embodiment;

FIG. 4 is a block diagram of a high-side control circuit according to the first embodiment;

FIG. 5 is a timing chart illustrating an operation example of a gate driver circuit according to the first embodiment;

FIG. 6 is a block diagram of an electronic device according to a second embodiment;

FIG. 7 is a circuit diagram of a charge pump circuit and a current source circuit according to a third embodiment;

FIG. 8 is a timing chart illustrating an operation example of the charge pump circuit and the current source circuit according to the third embodiment;

FIG. 9 is a circuit diagram illustrating an operation example of a charge pump circuit and a current source circuit according to comparative technology;

FIG. 10 is a circuit diagram of a charge pump circuit and a current source circuit according to a fourth embodiment; and

FIG. 11 is a timing chart illustrating an operation example of the charge pump circuit and the current source circuit according to the fourth embodiment.

### DETAILED DESCRIPTION

The invention will now be described by reference to the preferred embodiments. This does not intend to limit the scope of the present invention, but to exemplify the invention.

### Outline of Embodiments

An outline of some exemplary embodiments of the present disclosure will be described. This outline describes some concepts of one or more embodiments in a simplified manner for the purpose of basic understanding of the embodiments as a prelude to the detailed description below, and does not limit the breadth of the invention or disclosure. This outline is not a comprehensive outline of all possible embodiments, and is not intended to identify important elements of all embodiments or delineate the scope of some or all embodiments. For convenience, “one embodiment” may be used to refer to one embodiment (example or modification) or a plurality of embodiments (examples or modifications) disclosed in the present specification.

A gate driver circuit according to one embodiment includes: a high-side driver that drives a high-side transistor; a charge pump line to which a charge pump voltage higher than an input voltage of the high-side transistor and generated by a charge pump circuit is supplied; a current source circuit that is structured to be able to supply a constant current from the charge pump line to a bootstrap capacitor for driving the high-side transistor; and a current control circuit that controls on/off of supply of the constant current to the bootstrap capacitor by the current source circuit.

According to this configuration, the charging of the bootstrap capacitor can be assisted by supplying the constant current to the bootstrap capacitor, and a capacitor voltage can be more reliably set to a desired magnitude. As a result, the high-side transistor can be more reliably driven appropriately.

In one embodiment, the gate driver circuit may further include a voltage sensor that detects the capacitor voltage of the bootstrap capacitor. The current control circuit may control on/off of the supply of the constant current to the bootstrap capacitor by the current source circuit according to a comparison result between the capacitor voltage detected by the voltage sensor and a comparison voltage.

In one embodiment, the current control circuit may maintain the supply of the constant current to the bootstrap capacitor by the current source circuit on until the voltage sensor detects that the capacitor voltage has reached a threshold voltage. The current control circuit may switch the supply of the constant current to the bootstrap capacitor by the current source circuit from on to off in response to the voltage sensor detecting that the capacitor voltage has reached the threshold voltage.

In one embodiment, after the capacitor voltage reaches an upper threshold voltage as the threshold voltage, the current control circuit may switch the supply of the constant current to the bootstrap capacitor by the current source circuit from off to on in response to the voltage sensor detecting that the capacitor voltage has reduced to a lower threshold voltage lower than the upper threshold voltage.

In one embodiment, the current control circuit may switch the supply of the constant current to the bootstrap capacitor by the current source circuit from off to on in response to the voltage sensor detecting that the capacitor voltage is equal to or lower than a predetermined low threshold voltage.

In one embodiment, the current source circuit may be structured to be able to switch the magnitude of the constant current.

In one embodiment, the current source circuit may include a current mirror circuit and a switching circuit. The current mirror circuit may include two transistors forming a current mirror pair. The current mirror circuit may be structured such that a current flowing through one transistor of the two transistors is copied by the other transistor of the two transistors. The switching circuit may be structured to be able to switch a state of the current mirror circuit between a first state in which a current amount of the one transistor becomes zero and a second state in which the constant current flows through the one transistor. The other transistor may be provided between the charge pump line and the bootstrap capacitor.

In one embodiment, the charge pump circuit may include a charge pump capacitor. The charge pump circuit may alternately repeat a charging phase for charging the charge pump capacitor and a boosting phase for boosting a voltage at one end on the output side of the charge pump capacitor so as to generate the charge pump voltage. The switching circuit may operate in synchronization with the charge pump circuit so as to bring the current mirror circuit into the first state in the charging phase and bring the current mirror circuit into the second state in the boosting phase.

In one embodiment, the current source circuit may further include a rectifying element. The rectifying element may be provided between the other transistor and the bootstrap capacitor such that a direction from the other transistor to the bootstrap capacitor is a forward direction.

A switching circuit according to one embodiment may include the gate driver circuit; the bootstrap capacitor; the high-side transistor; and the charge pump circuit.

A three-phase gate driver according to one embodiment may control a three-phase bridge circuit including a first leg including a first high-side transistor and a first low-side transistor, a second leg including a second high-side transistor and a second low-side transistor, and a third leg including a third high-side transistor and a third low-side transistor. The three-phase gate driver may include: a first gate driver circuit controlling the first high-side transistor as the high-side transistor, the first gate driver circuit being the gate driver circuit; a second gate driver circuit controlling the second high-side transistor as the high-side transistor, the second gate driver circuit being the gate driver circuit; and a third gate driver circuit controlling the third high-side transistor as the high-side transistor, the third gate driver circuit being the gate driver circuit.

### Embodiments

Hereinafter, preferred embodiments will be described with reference to the drawings. The same or equivalent components, members, and processes illustrated in the drawings will be denoted by the same reference numerals, and repeated description will be omitted as appropriate. Further, the embodiments do not limit the disclosure and the invention, but are exemplary, and all features and combinations thereof described in the embodiments are not necessarily essential to the disclosure and the invention.

In the present specification, a “state where a member A is connected to a member B” includes not only a case where the member A and the member B are directly connected physically but also a case where the member A and the member B are indirectly connected via another member that does not substantially affect an electrical connection state or does not impair a function and an effect provided by connection.

Similarly, a “state where a member C is disposed (provided) between the members A and B” includes not only a case where the members A and C or the members B and C are directly connected but also a case where the members A and C or the members B and C are indirectly connected via another member that does not substantially affect an electrical connection state or does not impair a function and an effect provided by connection.

Further, in the present specification, a sign attached to an electric signal such as a voltage signal or a current signal, or a circuit element such as a resistor, a capacitor, or an inductor represents a voltage value, a current value, or a circuit constant (resistance value, capacitance value, and inductance) as necessary.

Further, in the present specification, the “integrally integrated” includes a case where all components of a circuit are formed on a semiconductor substrate and a case where main components of the circuit are integrally integrated, and some resistors, capacitors, and the like may be provided outside the semiconductor substrate for adjusting a circuit constant.

### First Embodiment

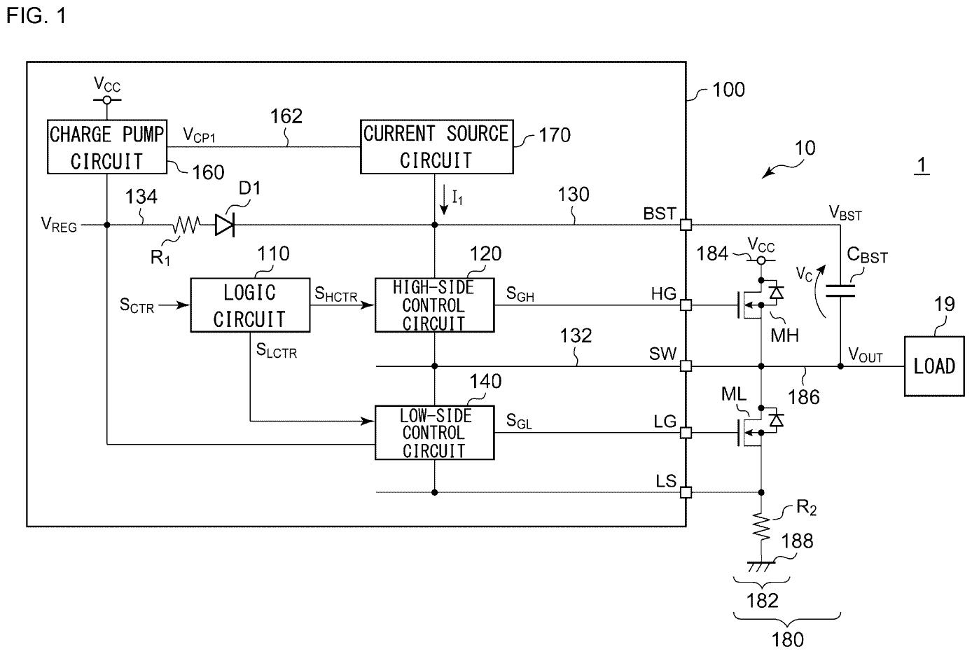

FIG. 1 is a block diagram of an electronic device 1 according to a first embodiment. The electronic device 1 according to the present embodiment includes a switching circuit 10 and a load 19. The load 19 operates according to an output voltage V_{OUT} of the switching circuit 10.

The switching circuit 10 according to the present embodiment includes a gate driver circuit 100 and a peripheral circuit 180. The gate driver circuit 100 and the peripheral circuit 180 are connected to each other via various pins (for example, a bootstrap pin BST, a high-side gate pin HG, a switching pin SW, a low-side gate pin LG, and a low-side source pin LS) included in the gate driver circuit 100.

The peripheral circuit 180 includes a half-bridge circuit 182 and a bootstrap capacitor C_{BST}.

The half-bridge circuit 182 is structured to generate an output voltage V_{OUT} according to an input voltage V_{CC}. The half-bridge circuit 182 according to the present embodiment includes a high-side transistor MH, a low-side transistor ML, and a resistor R₂.

Each of the high-side transistor MH and the low-side transistor ML includes an N-channel MOS transistor. The high-side transistor MH has a drain that is connected to a power supply line 184 (input line) to which the input voltage V_{CC} is supplied, a source that is connected to an output line 186 to which the output voltage V_{OUT} is supplied, and a gate that is connected to the high-side gate pin HG.

The output line 186 connects the switching pin SW and the load 19. The low-side transistor ML has a drain that is connected to the output line 186, a source that is connected to the low-side source pin LS, and a gate that is connected to the low-side gate pin LG. One end of the resistor R₂ is connected to the low-side source pin LS, and the other end of the resistor R₂ is connected to a ground line 188.

The bootstrap capacitor C_{BST} is provided to drive the high-side transistor MH. One end of the bootstrap capacitor C_{BST} is connected to the bootstrap pin BST, and the other end of the bootstrap capacitor C_{BST} is connected to the output line 186. When a voltage of the bootstrap pin BST is set to V_{BST}, a capacitor voltage V_{C} of the bootstrap capacitor C_{BST} is expressed by V_{C}=V_{BST}−V_{OUT}.

The gate driver circuit 100 drives the high-side transistor MH and the low-side transistor ML. The gate driver circuit 100 according to the present embodiment mainly includes a logic circuit 110, a high-side control circuit 120, a bootstrap line 130, a switching line 132, a power supply line 134, a low-side control circuit 140, a charge pump circuit 160, a charge pump line 162, a current source circuit 170, a resistor R₁, and a rectifying element D1. The gate driver circuit 100 may be a functional integrated circuit (IC) integrally integrated on one semiconductor chip.

The bootstrap line 130 is a line (or node) connected to the bootstrap pin BST. The switching line 132 is a line (or node) connected to the switching pin SW. The power supply line 134 is a line (or node) to which a power supply voltage V_{REG} of the bootstrap capacitor C_{BST} is supplied. The charge pump line 162 is a line (or node) to which a charge pump voltage V_{CP1} generated by the charge pump circuit 160 is supplied.

The logic circuit 110 generates a PWM signal for controlling the high-side control circuit 120 and the low-side control circuit 140 according to a control signal S_{CTR}. The control signal S_{CTR} may include, for example, a feedback signal of the output voltage V_{OUT}. The logic circuit 110 generates, for example, a high-side control signal S_{HCTR} to be transmitted to the high-side control circuit 120 and a low-side control signal S_{LCTR} to be transmitted to the low-side control circuit 140.

The high-side control circuit 120 performs control related to driving of the high-side transistor MH. The high-side control circuit 120 according to the present embodiment generates a high-side gate signal S_{GH} according to the high-side control signal S_{HCTR} from the logic circuit 110. The high-side gate signal S_{GH} is supplied to the gate of the high-side transistor MH through the high-side gate pin HG. In addition, the high-side control circuit 120 according to the present embodiment generates a control signal S_{SW} for controlling the operation of the current source circuit 170.

The low-side control circuit 140 performs control related to driving of the low-side transistor ML. For example, the low-side control circuit 140 generates a low-side gate signal S_{GL} according to the low-side control signal S_{LCTR} from the logic circuit 110. The low-side gate signal S_{GL} is supplied to the gate of the low-side transistor ML through the low-side gate pin LG.

The charge pump circuit 160 generates a charge pump voltage V_{CP1} higher than the input voltage V_{CC} of the half-bridge circuit 182 (or the high-side transistor MH). The charge pump circuit 160 according to the present embodiment generates the charge pump voltage V_{CP1} in which the power supply voltage V_{REG} is superimposed on the input voltage V_{CC}.

The current source circuit 170 is structured to be able to supply a constant current I₁ from the charge pump line 162 to the bootstrap capacitor C_{BST}. The constant current I₁ is supplied to the bootstrap capacitor C_{BST} through the bootstrap line 130 and the bootstrap pin BST. As a result, the bootstrap capacitor C_{BST} is charged, and the capacitor voltage V_{C} increases.

The resistor R₁ and the rectifying element D1 constitute a bootstrap circuit together with the bootstrap capacitor C_{BST}. One end of the resistor R₁ is connected to the power supply line 134. The rectifying element D1 includes a diode. The rectifying element D1 has an anode connected to the other end of the resistor R₁, and a cathode connected to the bootstrap line 130.

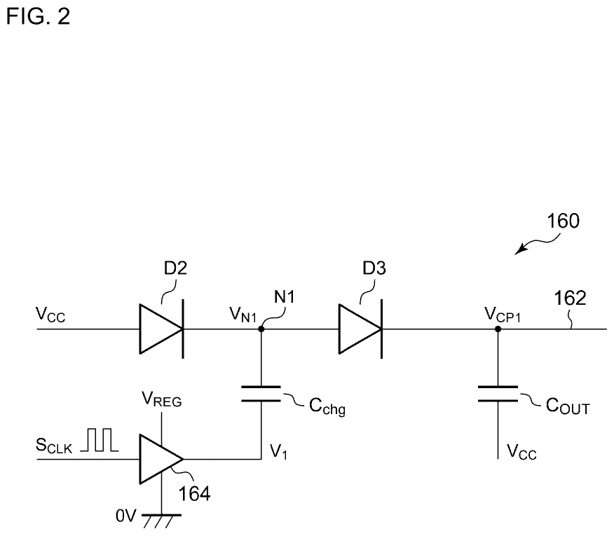

FIG. 2 is a circuit diagram of the charge pump circuit 160 according to the present embodiment. The charge pump circuit 160 according to the present embodiment includes a buffer 164, rectifying elements D2 and D3, a charge pump capacitor C_{chg}, and an output capacitor C_{OUT}. Note that the charge pump capacitor C_{chg} and the output capacitor C_{OUT} may be externally attached to a semiconductor chip constituting the gate driver circuit 100. By externally attaching these capacitors, a capacitance of about several nF, which is difficult to realize in an IC chip, can be realized. As a result, for example, a current capability of about several tens of mA can be realized.

Each of the rectifying elements D2 and D3 includes a diode. The input voltage V_{CC} is supplied to an anode of the rectifying element D2, and a cathode of the rectifying element D2 is connected to an anode of the rectifying element D3. A cathode of the rectifying element D3 is connected to the charge pump line 162. One end of the charge pump capacitor C_{chg} is connected to the cathode of the rectifying element D2. One end of the output capacitor C_{OUT} is connected to the charge pump line 162, and the input voltage V_{CC} is supplied to the other end of the output capacitor C_{OUT}. A clock signal S_{CLK} from an oscillator (not illustrated) is input to the buffer 164, and the buffer 164 generates an output voltage V₁ according to the clock signal S_{CLK}. The output voltage V₁ is supplied to the other end of the charge pump capacitor C_{chg}.

The operation of the charge pump circuit 160 will be described. The charge pump circuit 160 alternately repeats the charging phase and the boosting phase so as to generate the charge pump voltage V_{CP1} higher than the input voltage V_{CC}. The charging phase is a phase in which the charge pump circuit 160 charges the charge pump capacitor C_{chg}. The boosting phase is a phase in which the charge pump circuit 160 boosts the voltage at one end on the output side of the charge pump capacitor C_{chg}. Here, the voltage at one end on the output side of the charge pump capacitor C_{chg} is a voltage V_{N1} at the node N1 between the rectifying element D2 and the rectifying element D3. In the present embodiment, the phase of the charge pump circuit 160 is the charging phase when the clock signal S_{CLK} is at a low level, and is the boosting phase when the clock signal S_{CLK} is at a high level.

In the charging phase (that is, when the clock signal S_{CLK} is at a low level), the output voltage V₁ of the buffer 164 becomes 0 V. When the voltage drop across the rectifying element D2 is represented as V_{f}, the voltage V_{N1} at the node N1 is V_{N1}=V_{CC}−V_{f}. As a result, the charge pump capacitor C_{chg} is charged with V_{CC}−V_{f}. In the boosting phase (that is, when the clock signal S_{CLK} is at a high level), the output voltage V₁ of the buffer 164 becomes the power supply voltage V_{REG}. At this time, since the voltage across the charge pump capacitor C_{chg} is maintained at V_{CC}−V_{f}, the voltage V_{N1} at the node N1 is V_{N1}=V_{CC}−V_{f}+V_{REG}. The output capacitor C_{OUT} is charged by the voltage V_{N1} (=V_{CC}−V_{f}+V_{REG}) at this time. By repeating the charging phase and the boosting phase, the charge pump voltage V_{CP1} is V_{CP1}=V_{CC}−2V₄+V_{REG}.

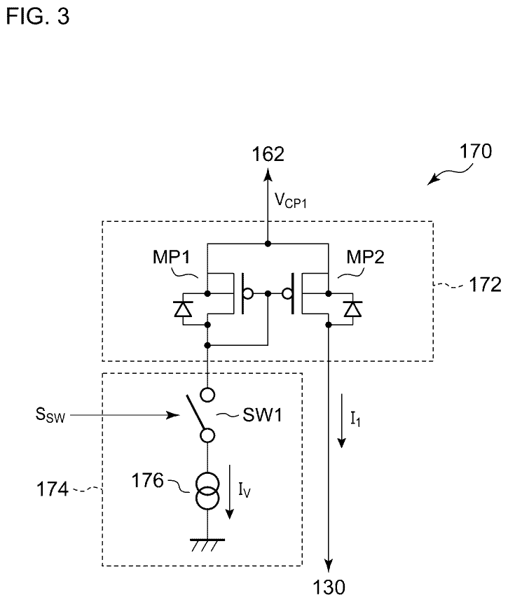

FIG. 3 is a circuit diagram of the current source circuit 170 according to the present embodiment. The current source circuit 170 according to the present embodiment includes a current mirror circuit 172 and a switching circuit 174.

The current mirror circuit 172 includes two transistors MP1 and MP2 forming a current mirror pair, and is structured such that a current flowing through one transistor MP1 is copied by the other transistor MP2. Each of the transistors MP1 and MP2 includes a P-channel MOS transistor. A gate of the transistor MP1 is connected to a drain of the transistor MP1 in common with a gate of the transistor MP2. A source of the transistor MP1 is connected to the charge pump line 162 in common with a source of the transistor MP2. Therefore, the charge pump voltage V_{CP1} is supplied to the sources of the transistors MP1 and MP2. A drain of the transistor MP2 is connected to the bootstrap line 130.

The switching circuit 174 is structured to be able to switch a state of the current mirror circuit 172 between a first state in which a current amount of the transistor MP1 becomes 0 and a second state in which a constant current flows through the transistor MP1. The switching circuit 174 according to the present embodiment includes a switch SW1 and a current source 176. The switch SW1 may include various switch elements, and is provided between the drain of the transistor MP1 and the current source 176. On and off states of the switch SW1 are controlled by the control signal S_{SW}. The current source 176 is structured to be able to generate a current I_{V} that is a constant current.

When the switch SW1 is turned on, the current I_{V} generated by the current source 176 flows through the transistor MP1. The transistor MP2 copies the current I_{V} flowing through the transistor MP1 to generate the constant current I₁. When the switch SW1 is turned off, no current flows through the transistor MP2, and the current amount of the transistor MP1 becomes zero. As a result, the current also does not flow through the transistor MP2 (I₁=0).

The current source circuit 170 according to the present embodiment is structured to be able to switch the magnitude of the constant current I₁. Specifically, the current source 176 is structured to be able to switch the magnitude of the current I_{V}. The magnitude of the constant current I₁ can be switched by switching the magnitude of the current I_{V}. The magnitude of the current I_{V} may be switched by, for example, the high-side control circuit 120.

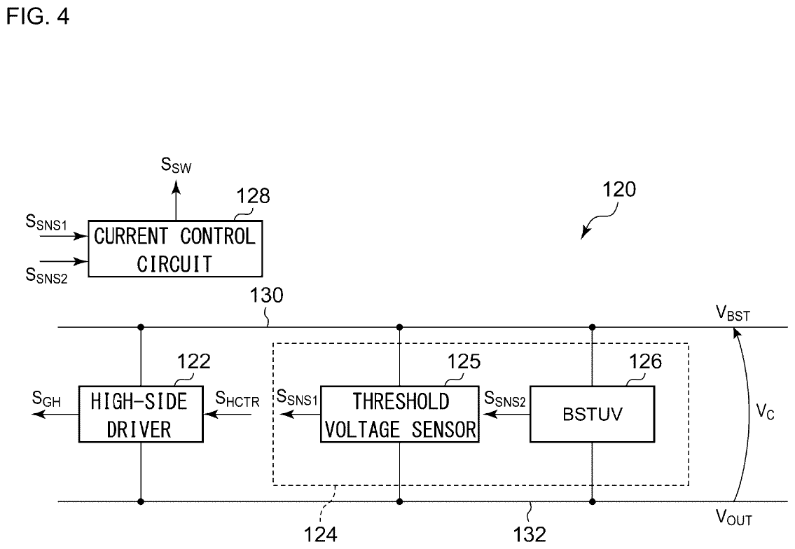

FIG. 4 is a block diagram of the high-side control circuit 120 according to the present embodiment. The high-side control circuit 120 according to the present embodiment includes a high-side driver 122, a voltage sensor 124, and a current control circuit 128.

The high-side driver 122 drives the high-side transistor MH. The high-side driver 122 according to the present embodiment generates a high-side gate signal S_{GH} according to the high-side control signal S_{HCTR} by using the bootstrap voltage V_{BST} of the bootstrap line 130.

The voltage sensor 124 detects the voltage between the bootstrap line 130 and the switching line 132, that is, the capacitor voltage V_{C} of the bootstrap capacitor C_{BST}. The voltage sensor 124 includes a threshold voltage sensor 125 and a low voltage sensor 126.

The threshold voltage sensor 125 generates a sensor signal S_{SNS1} indicating a comparison result between a threshold voltage and the capacitor voltage V_{C}. The sensor signal S_{SNS1} may include a signal indicating a comparison result between a lower threshold voltage and the capacitor voltage V_{C}, a signal indicating a comparison result between an upper threshold voltage higher than the lower threshold voltage and the capacitor voltage V_{C}, and the like. The sensor signal S_{SNS1} is transmitted to the current control circuit 128. The threshold voltage sensor 125 may include a comparator for comparing voltages as necessary.

The low voltage sensor 126 generates a sensor signal S_{SNS2} indicating a comparison result between a predetermined low threshold voltage and the capacitor voltage V_{C}. This predetermined low threshold voltage is lower than the lower threshold voltage, and may be set to a magnitude that may cause an unintended effect on the driving of the high-side transistor MH if the capacitor voltage V_{C} falls below the predetermined low threshold voltage. The sensor signal S_{SNS2} is transmitted to the current control circuit 128. The low voltage sensor 126 may include a comparator for comparing voltages as necessary.

The current control circuit 128 controls on/off of the supply of the constant current I₁ to the bootstrap capacitor C_{BST} by the current source circuit 170. The current control circuit 128 according to the present embodiment generates the control signal S_{SW} and controls on/off of the switch SW1 of the current source circuit 170. When the switch SW1 is turned on, the supply of the constant current I₁ is turned on (I₁>0), and when the switch SW1 is turned off, the supply of the constant current I₁ is turned off (I₁=0).

The current control circuit 128 according to the present embodiment controls on/off of the supply of the constant current I₁ to the bootstrap capacitor C_{BST} by the current source circuit 170 according to a comparison result between the capacitor voltage V_{C} detected by the voltage sensor 124 and the comparison voltage. The comparison voltage is a voltage to be compared with the capacitor voltage V_{C}, and includes, for example, the lower threshold voltage, the upper threshold voltage, and the predetermined low threshold voltage.

The current control circuit 128 may maintain the supply of the constant current I₁ to the bootstrap capacitor C_{BST} by the current source circuit 170 on until the threshold voltage sensor 125 detects that the capacitor voltage V_{C} has reached the upper threshold voltage. As a result, even in a case where the load 19 is heavy and a duty ratio is high, the capacitor voltage V_{C} can be sufficiently increased more reliably by supplying the constant current I₁ to the bootstrap capacitor C_{BST}.

The current control circuit 128 may switch the supply of the constant current I₁ to the bootstrap capacitor C_{BST} by the current source circuit 170 from on to off in response to the threshold voltage sensor 125 detecting that the capacitor voltage V_{C} has reached the upper threshold voltage. As a result, the capacitor voltage V_{C} is suppressed from excessively increasing.

After the capacitor voltage V_{C} reaches the upper threshold voltage, the current control circuit 128 may switch the supply of the constant current I₁ to the bootstrap capacitor C_{BST} by the current source circuit 170 from off to on in response to the threshold voltage sensor 125 detecting that the capacitor voltage V_{C} has reduced to the lower threshold voltage. As a result, it is possible to sufficiently increase the capacitor voltage V_{C} more reliably as described above.

The current control circuit 128 may switch the supply of the constant current I₁ to the bootstrap capacitor C_{BST} by the current source circuit 170 from off to on in response to the low voltage sensor 126 detecting that the capacitor voltage V_{C} is equal to or lower than the predetermined low threshold voltage. As a result, the occurrence of a situation in which the operation of the high-side transistor MH stops due to the decrease in the capacitor voltage V_{C} is suppressed.

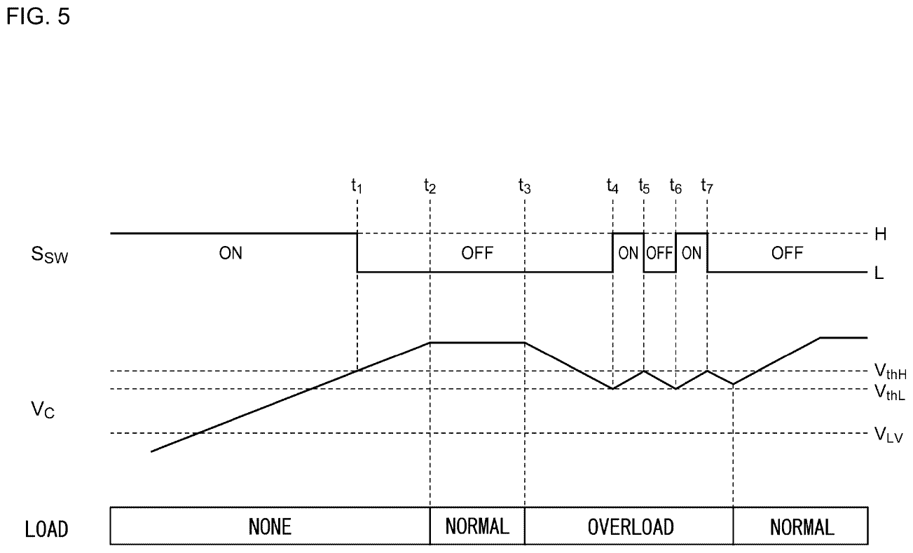

FIG. 5 is a timing chart illustrating an operation example of the gate driver circuit 100 according to the present embodiment. Here, it is assumed that the high-side transistor MH and the low-side transistor ML of the half-bridge circuit 182 are switched according to control by the gate driver circuit 100.

FIG. 5 illustrates the control signal S_{SW} of the switch SW1 of the current source circuit 170, the capacitor voltage V_{C}, and the state of the load 19. It is assumed that the switch SW1 is turned on when the control signal S_{SW} is at a high level (H) and is turned off when the control signal S_{SW} is at a low level (L). V_{thL} is the lower threshold voltage, V_{thH} is the upper threshold voltage, and V_{LV} is the predetermined low threshold voltage.

Before time t₁, there is no load 19, and the switch SW1 is turned on. At this time, the capacitor voltage V_{C} increases due to the operation of the bootstrap circuit and the supply of the constant current I₁ by the current source circuit 170. When the capacitor voltage V_{C} reaches the upper threshold voltage V_{thH} at time t₁, the switch SW1 switches from on to off. While the switch SW1 is turned off, the constant current I₁ is not supplied by the current source circuit 170, and the capacitor voltage V_{C} increases due to the operation of the bootstrap circuit.

When the load 19 (normal level) is connected to the switching circuit 10 at time t₂, an increase in the capacitor voltage V_{C} stops (or becomes gentle). When the load 19 enters an overload state at time t₃, the bootstrap circuit alone is insufficient in capability, and the capacitor voltage V_{C} starts to decrease.

At time t₄, when the capacitor voltage V_{C} reaches the lower threshold voltage V_{thL}, the switch SW1 is switched from off to on. As a result, the capacitor voltage V_{C} starts to increase by the supply of the constant current I₁ by the current source circuit 170.

Thereafter, at times t₅, t₆, and t₇, on/off of the switch SW1 is switched each time the capacitor voltage V_{C} reaches the upper threshold voltage V_{thH} or the lower threshold voltage V_{thL}. As a result, even in an overload state, the capacitor voltage V_{C} can be kept within an appropriate voltage range (specifically, between the upper threshold voltage V_{thH} and the lower threshold voltage V_{thL}).

When the capacitor voltage V_{C} becomes equal to or lower than the threshold voltage V_{LV}, the switch SW1 may be always turned on except for a case where the capacitor voltage V_{C} is intentionally decreased. As a result, it is possible to more reliably suppress the stop of the operation of the high-side driver 122.

The configurations of the gate driver circuit 100 and the switching circuit 10 using the same according to the present embodiment and the operation example of the gate driver circuit 100 have been described above. The gate driver circuit 100 according to the present embodiment includes the high-side driver 122, the current control circuit 128, the charge pump line 162, and the current source circuit 170. The high-side driver 122 drives the high-side transistor MH. The charge pump line 162 is supplied with the charge pump voltage V_{CP1} generated by the charge pump circuit 160, which is higher than the input voltage V_{CC} of the high-side transistor MH. The current source circuit 170 is structured to be able to supply the constant current I₁ from the charge pump line 162 to the bootstrap capacitor C_{BST} for driving the high-side transistor MH. The current control circuit 128 controls on/off of the supply of the constant current I₁ to the bootstrap capacitor C_{BST} by the current source circuit 170.

According to this configuration, the charging of the bootstrap capacitor C_{BST} can be assisted by supplying the constant current I₁ to the bootstrap capacitor C_{BST}, and the capacitor voltage V_{C} can be more reliably set to a desired magnitude. As a result, the high-side transistor MH can be more reliably driven appropriately.

Here, it is considered that the bootstrap capacitor C_{BST} is charged using only the bootstrap circuit without the charge pump circuit 160 and the current source circuit 170, and the high-side transistor MH is driven using the capacitor voltage V_{C}. In this case, when PWM control is performed at a high duty ratio in an overload state, a time (that is, a time for which the bootstrap capacitor C_{BST} is charged) for which the low-side transistor ML is turned on is shortened. Therefore, there is a possibility that the bootstrap capacitor C_{BST} is not sufficiently charged.

According to the gate driver circuit 100 according to the present embodiment, the current source circuit 170 can supply the constant current I₁ from the charge pump line 162 to the bootstrap capacitor C_{BST} even in a case of a high duty ratio in an overload state. As a result, the bootstrap capacitor C_{BST} can be sufficiently charged.

In addition, it is considered that the high-side transistor MH is driven by the charge pump voltage V_{CP1} of the charge pump circuit 160 instead of the bootstrap circuit. In this case, as compared with the case where the high-side transistor MH is driven only by the bootstrap circuit as described above, the high-side transistor MH can be operated at a higher voltage. Therefore, even in the case of a high duty ratio, the high-side transistor MH can be appropriately driven.

However, when the high-side transistor MH is driven by the charge pump voltage V_{CP1}, a high voltage is always applied to the high-side driver 122, so that it is necessary to use an element having a high withstand voltage for the high-side driver 122. In general, since the area of the element increases as the withstand voltage increases, there is a disadvantage that the area of the high-side driver 122 increases. In addition, since the high voltage of the charge pump voltage V_{CP1} is always used, the efficiency of power consumption also decreases (for example, 50% or less).

On the other hand, according to the gate driver circuit 100 of the present embodiment, it is possible to switch on/off of the supply of the constant current I₁ from the charge pump line 162 to the bootstrap capacitor C_{BST}. Therefore, it is possible to suppress the capacitor voltage V_{C} from becoming too high, and it is not necessary to use an element having a high withstand voltage as in a case where the high-side transistor MH is driven only by the charge pump voltage V_{CP1}, and it is possible to suppress an increase in the area of the high-side driver 122. In addition, since the supply of the constant current I₁ is performed supplementarily (partially), the efficiency of power consumption is also improved.

### Second Embodiment

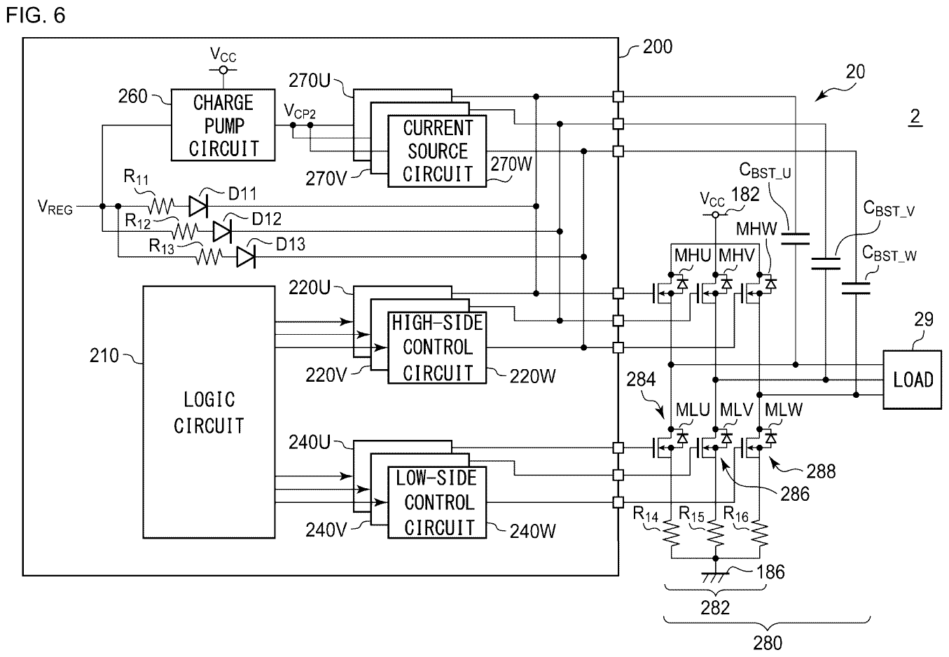

FIG. 6 is a block diagram of an electronic device 2 according to a second embodiment. The electronic device 2 according to the second embodiment includes a switching circuit 20 and a load 29. The switching circuit 20 according to the second embodiment includes a three-phase gate driver 200 and a peripheral circuit 280. Note that one or a plurality of elements described for the electronic device 1 according to the above embodiment may be applied to the electronic device 2 according to the second embodiment as necessary.

The load 29 operates in response to an output signal (more specifically, an output signal of a three-phase bridge circuit 282 to be described later) from the switching circuit 20. The load 29 may be, for example, a three-phase motor or the like.

The peripheral circuit 280 includes a three-phase bridge circuit 282 and three bootstrap capacitors (a first bootstrap capacitor C_{BST_U}, a second bootstrap capacitor C_{BST_V}, and a third bootstrap capacitor C_{BST_W}).

The three-phase bridge circuit 282 includes a first leg 284, a second leg 286, and a third leg 288. The first leg 284 includes a first high-side transistor MHU, a first low-side transistor MLU, and a resistor R₁₄. The second leg 286 includes a second high-side transistor MHV, a second low-side transistor MLV, and a resistor R₁₅. The third leg 288 includes a third high-side transistor MHW, a third low-side transistor MLW, and a resistor R₁₆. These legs may be structured similarly to a half-bridge circuit 182 according to the first embodiment.

The three-phase gate driver 200 mainly includes a logic circuit 210, a first high-side control circuit 220U, a second high-side control circuit 220V, a third high-side control circuit 220W, a first low-side control circuit 240U, a second low-side control circuit 240V, a third low-side control circuit 240W, a charge pump circuit 260, a first current source circuit 270U, a second current source circuit 270V, a third current source circuit 270W, resistors R₁₁ to R₁₃, and rectifying elements D11 to D13.

The three-phase gate driver 200 includes three gate driver circuits (first to third gate driver circuits). In the second embodiment, the logic circuit 210 and the charge pump circuit 260 are shared by the three gate driver circuits. Specifically, the logic circuit 210, the first high-side control circuit 220U, the first low-side control circuit 240U, the charge pump circuit 260, the first current source circuit 270U, the resistor R₁₁, and the rectifying element D11 constitute a first gate driver circuit. Further, the logic circuit 210, the second high-side control circuit 220V, the second low-side control circuit 240V, the charge pump circuit 260, the second current source circuit 270V, the resistor R₁₂, and the rectifying element D12 constitute a second gate driver circuit. Further, the logic circuit 210, the third high-side control circuit 220W, the third low-side control circuit 240W, the charge pump circuit 260, the third current source circuit 270W, the resistor R₁₃, and the rectifying element D13 constitute a third gate driver circuit.

Hereinafter, when the first high-side control circuit 220U, the second high-side control circuit 220V, and the third high-side control circuit 220W are not particularly distinguished, these are also collectively referred to as a “high-side control circuit 220”. Further, when the first low-side control circuit 240U, the second low-side control circuit 240V, and the third low-side control circuit 240W are not particularly distinguished, these are also collectively referred to as a “low-side control circuit 240”. Further, when the first current source circuit 270U, the second current source circuit 270V, and the third current source circuit 270W are not particularly distinguished, these are also collectively referred to as a “current source circuit 270”.

The high-side control circuit 220 according to the second embodiment may have substantially the same configuration as the high-side control circuit 120 according to the first embodiment. Further, the low-side control circuit 240 according to the second embodiment may have substantially the same configuration as the low-side control circuit 140 according to the first embodiment. Further, the charge pump circuit 260 according to the second embodiment has substantially the same configuration as the charge pump circuit 160 according to the first embodiment, and generates a charge pump voltage V_{CP2}. Further, the current source circuit 270 according to the second embodiment may have substantially the same configuration as the current source circuit 170 according to the first embodiment.

The resistor R₁₁ and the rectifying element D11 constitute a bootstrap circuit of the first gate driver circuit together with the first bootstrap capacitor C_{BST_U}. The resistor R₁₂ and the rectifying element D12 constitute a bootstrap circuit of the second gate driver circuit together with the second bootstrap capacitor C_{BST_V}. The resistor R₁₃ and the rectifying element D13 constitute a bootstrap circuit of the third gate driver circuit together with the third bootstrap capacitor C_{BST_W}.

The logic circuit 210 controls the high-side control circuit 220 and the low-side control circuit 240 similarly to the logic circuit 110 according to the above embodiment. The high-side control circuit 220 drives a corresponding high-side transistor of the three-phase bridge circuit 282 while using the charge pump circuit 260 and the current control circuit 128 as necessary. The low-side control circuit 240 drives a corresponding low-side transistor of the three-phase bridge circuit 282.

### Third Embodiment

A third embodiment is different from the second embodiment in a configuration of a charge pump circuit and an operation of a current source circuit in a three-phase gate driver. An electronic device according to the third embodiment has substantially the same configuration as an electronic device 2 according to the second embodiment except for the charge pump circuit.

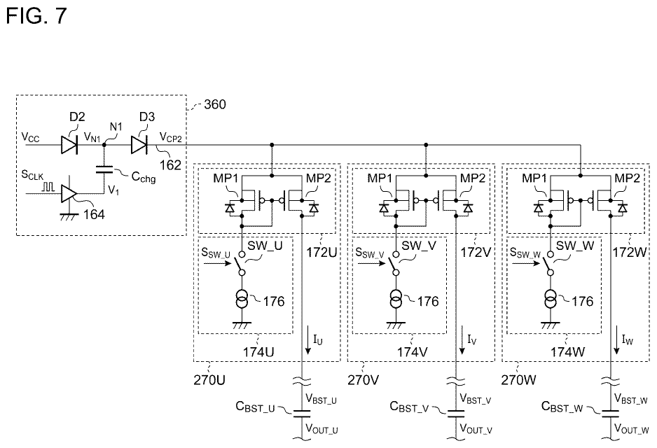

FIG. 7 is a circuit diagram of a charge pump circuit 360, a first current source circuit 270U, a second current source circuit 270V, and a third current source circuit 270W according to the third embodiment. As illustrated in FIG. 7, the charge pump circuit 360 according to the third embodiment is different from the charge pump circuits 160 and 260 according to the above embodiments in that an output capacitor C_{OUT} is not included.

A current source circuit 270 has substantially the same configuration as the current source circuit 170 according to the first embodiment. Specifically, the first current source circuit 270U includes a current mirror circuit 172U and a switching circuit 174U, the second current source circuit 270V includes a current mirror circuit 172V and a switching circuit 174V, and the third current source circuit 270W includes a current mirror circuit 172W and a switching circuit 174W.

Similarly to the switching circuit 174 according to the first embodiment, the switching circuit 174U of the first current source circuit 270U switches the state of the current mirror circuit 172U between a first state in which the current amount of the transistor MP1 becomes 0 and a second state in which a constant current flows through the transistor MP1. Similarly, the switching circuit 174V switches the state of the current mirror circuit 172V between the first state and the second state, and the switching circuit 174W switches the state of the current mirror circuit 172W between the first state and the second state. The switching circuits 174U, 174V, and 174W include a first switch SW_U, a second switch SW_V, and a third switch SW_W, respectively, in addition to the current source 176.

On and off states of the first switch SW_U are controlled by a control signal S_{SW_U}. Further, on and off states of the second switch SW_V are controlled by a control signal S_{SW_V}. Further, on and off states of the third switch SW_W are controlled by a control signal S_{SW_W}. These control signals S_{SW_U}, S_{SW_V}, and S_{SW_W} may be generated by a corresponding high-side control circuit.

The charge pump circuit 360 according to the present embodiment alternately repeats a charging phase and a boosting phase, similarly to the charge pump circuits 160 and 260 according to the above embodiments. However, the charge pump circuit 360 according to the present embodiment does not include an output capacitor. Therefore, the charge pump voltage V_{CP2} according to the present embodiment rapidly changes as compared with the charge pump voltage according to the above embodiment every time the phase is switched.

Each of the switching circuits 176U to 176W according to the present embodiment operates in synchronization with the charge pump circuit 360. Specifically, each of the switching circuits 176U to 176W brings a corresponding current mirror circuit among the current mirror circuits 172U to 172W into the first state in the charging phase. Further, each of the switching circuits 176U to 176W brings a corresponding current mirror circuit among the current mirror circuits 172U to 172W into the second state in the boosting phase.

The currents I_{U} to I_{W} are output from the current source circuit 270 including the current mirror circuits 172U to 172W in the second state. The current I_{U} output from the first current source circuit 270U is supplied to the first bootstrap capacitor C_{BST_U}, the current I_{V} output from the second current source circuit 270V is supplied to the second bootstrap capacitor C_{BST_V}, and the current I_{W} output from the third current source circuit 270W is supplied to the third bootstrap capacitor C_{BST_W}.

Here, the voltage V_{BST_U} is a voltage at one end of the first bootstrap capacitor C_{BST_U} on the first current source circuit 270U side. Further, the voltage V_{BST_V} is a voltage at one end of the second bootstrap capacitor C_{BST_V} on the second current source circuit 270V side. Further, the voltage V_{BST_W} is a voltage at one end of the third bootstrap capacitor C_{BST_W} on the third current source circuit 270W side. Further, the voltage V_{OUT_U} is the output voltage of the first leg 284, the voltage V_{OUT_V} is the output voltage of the second leg 286, and the voltage V_{OUT_W} is the output voltage of the third leg 288.

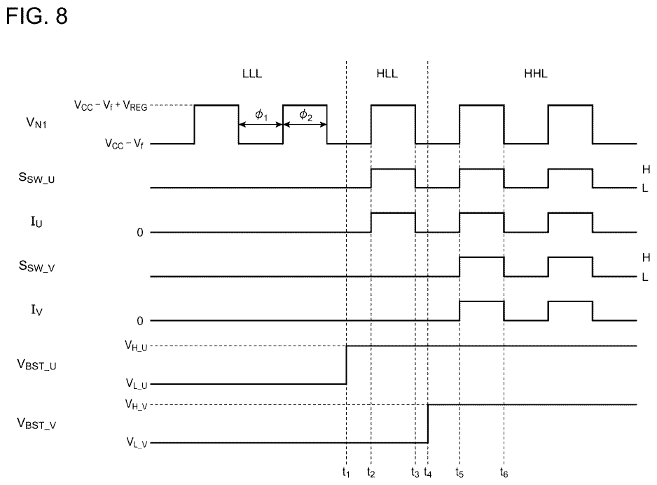

FIG. 8 is a timing chart illustrating an operation example of the charge pump circuit 360 and the current source circuit 270 according to the third embodiment.

The labels “LLL”, “HLL”, and “HHL” illustrated at the top of FIG. 8 indicate the logic of the three-phase bridge circuit 282. Each label indicates the logic of the first leg 284, the second leg 286, and the third leg 288 in order from the left end. The label “H” (high) indicates that the corresponding high-side transistor is turned on and the corresponding low-side transistor is turned off. The label “L” (low) indicates that the corresponding high-side transistor is turned off and the corresponding low-side transistor is turned on. For example, the label “HLL” indicates that the logic of the first leg 284 is high and the logic of each of the second and third legs 286 and 288 is low.

On the lower side of the label of the logic of the three-phase bridge circuit 282, a voltage V_{N1} of a node N1 of the charge pump circuit 360, a control signal S_{SW_U} of the first switch SW_U, a current I_{U} output from the first current source circuit 270U, a control signal S_{SW_V} of the second switch SW_V, a current I_{V} output from the second current source circuit 270V, a voltage V_{BST_U} at one end of the first bootstrap capacitor C_{BST_U}, and a voltage V_{BST_V} at one end of the second bootstrap capacitor C_{BST_V} are illustrated in order from the top.

The voltage V_{N1} periodically changes according to switching of a charging phase φ₁ and a boosting phase φ₂ of the charge pump circuit 360. Specifically, the voltage V_{N1} becomes V_{N1}=V_{CC}−V_{f}in the charging phase φ₁, and becomes V_{N1}=V_{CC}−V_{f}+V_{REG} in the boosting phase φ₂.

The control signals S_{SW_U} and S_{SW_V} are high (H) or low (L). When the control signals S_{SW_U} and S_{SW_V} are high, the corresponding switch (the first switch SW_U or the second switch SW_V) is turned on. When the control signals S_{SW_U} and S_{SW_V} are low, the corresponding switch (the first switch SW_U or the second switch SW_V) is turned off. Although the control signal S_{SW_W} of the third switch SW_W is not illustrated in FIG. 8, the logic of the third leg 288 is always low in a time range illustrated in FIG. 8, and the control signal S_{SW_W} is also always low.

Before time t₁, the logic of the three-phase bridge circuit 282 is “LLL”. Therefore, both the control signals S_{SW_U} and S_{SW_V} are low, and the currents I_{U} and I_{V} are not output (I_{U} =0, I_{V}=0). In addition, each of a voltage (that is, V_{BST_U}-VOUT_U) across the first bootstrap capacitor C_{BST_U} and a voltage (that is, V_{BST_V}−V_{OUT_V}) across the second bootstrap capacitor C_{BST_V} is the lower threshold voltage V_{thL}, and V_{BST_U}=V_{L_U} and V_{BST_V}=V_{L_V} are satisfied.

At time t₁, the logic of the three-phase bridge circuit 282 changes to “HLL”. Therefore, the logic of the first leg 284 becomes high, the first high-side transistor MHU is turned on, and the first low-side transistor MLU is turned off. As a result, the voltage V_{BST_U} substantially increases from V_{L_U} by the input voltage V_{CC} and becomes V_{H_U}.

Since the voltage across the first bootstrap capacitor C_{BST_U} is the lower threshold voltage V_{thL}, the first current source circuit 270U operates to supply a constant current to the first bootstrap capacitor C_{BST_U} in response to the logic of the first leg 284 becoming high. Specifically, the control signal S_{SW_U} changes in synchronization with the charge pump circuit 360. More specifically, the control signal S_{SW_U} becomes low in the charging phase φ₁ and becomes high in the boosting phase φ₂.

For example, at time t₂, the phase of the charge pump circuit 360 is switched from the charging phase φ₁ to the boosting phase φ₂. The control signal S_{SW_U} changes from low to high according to the switching of the phase. At time t₃, the phase of the charge pump circuit 360 is switched from the boosting phase φ₂ to the charging phase φ₁. The control signal S_{SW_U} changes from high to low according to the switching of the phase.

During a period in which the control signal S_{SW_U} is low (for example, times t₁ to t₂ and t₃ to t₄), since the first switch SW_U is turned off, the current I_{U} is not output (I_{U}=0). During a period in which the control signal S_{SW_U} is high (for example, times t₂ to t₃), since the first switch SW_U is turned on, the current I_{U} is output (I_{U}>0). The first bootstrap capacitor C_{BST_U} is charged by the output current I_{U}.

At time t₄, the logic of the three-phase bridge circuit 282 changes to “HHL”. Therefore, the logic of the second leg 286 becomes high, the second high-side transistor MHV is turned on, and the second low-side transistor MLV is turned off. As a result, the voltage V_{BST_V} substantially increases from V_{L_V} by the input voltage V_{CC} and becomes V_{H_V}.

Since the voltage across the second bootstrap capacitor C_{BST_V} is the lower threshold voltage V_{thL}, the second current source circuit 270V operates to supply a constant current to the second bootstrap capacitor C_{BST_V} in response to the logic of the second leg 286 becoming high. Specifically, the control signal S_{SW_V} changes in synchronization with the charge pump circuit 360. More specifically, similarly to the control signal S_{SW_U}, the control signal S_{SW_V} becomes low in the charging phase φ₁ and becomes high in the boosting phase φ₂.

For example, in a period (for example, times t₄ to t₅) in which the control signals S_{SW_U} and S_{SW_V} are low, each of the first switch SW_U and the second switch SW_V is turned off. Therefore, the currents I_{U} and I_{V} are not output (I_{U}=0, I_{V}=0). In a period in which the control signals S_{SW_U} and S_{SW_V} are high (for example, times t₅ to t₆), the first switch SW_U and the second switch SW_V are turned on. Therefore, the currents I_{U} and I_{V} are output (I_{U}>0, I_{V}>0). The first bootstrap capacitor C_{BST_U} and the second bootstrap capacitor C_{BST_V} are charged by the output currents I_{U} and I_{V}.

The operation example of the charge pump circuit 360 and the current source circuit 270 according to the present embodiment has been described above. Although the example in which the logic of each leg is high or low has been described in the present operation example, the logic of each leg may take Z logic. The current source circuit corresponding to the leg taking the Z logic may operate in synchronization with the charge pump circuit 360, similarly to the current source circuit corresponding to the leg taking the logic of the high.

According to the three-phase gate driver of the present embodiment, the current source circuit 270 operates in synchronization with the charge pump circuit 360 as described above. As a result, the backward flow of the current through the body diode of the transistor MP2 of the current mirror circuits 172U to 172W is suppressed.

Further, according to the three-phase gate driver of the present embodiment, since the backward flow of the current through the body diode of the transistor MP2 is suppressed, it is possible to appropriately assist each bootstrap circuit without providing the output capacitor in the charge pump circuit 360.

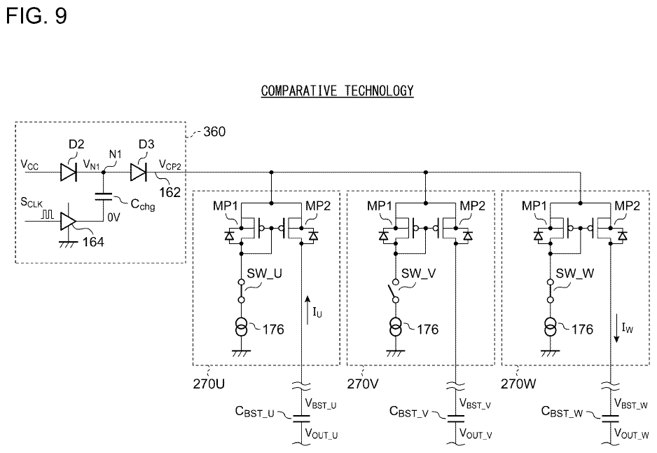

The advantage of the three-phase gate driver according to the present embodiment is further clarified by comparison with comparative technology. FIG. 9 is a circuit diagram illustrating an operation example of the charge pump circuit 360 and the current source circuit 270 according to the comparative technology. Here, it is assumed that the logic of the three-phase bridge circuit 282 is “HLZ” and the phase of the charge pump circuit 360 is the charging phase φ₁. In addition, it is assumed that each of the voltage across the first bootstrap capacitor C_{BST_U} and the voltage across the third bootstrap capacitor C_{BST_W} is the lower threshold voltage V_{thL}.

In the comparative technology, the current source circuit 270 operates asynchronously with the charge pump circuit 360. Specifically, in the first current source circuit 270U corresponding to the high logic leg and the third current source circuit 270W corresponding to the Z logic leg, the first switch SW_U and the third switch SW_W are maintained on regardless of a change in phase in the charge pump circuit 360.

When the charge pump circuit 360 is in the charging phase, the voltage V_{N1} at the node N1 of the charge pump circuit 360 becomes the voltage V_{N1}=V_{CC}−V_{f}. At this time, it is assumed that the voltage V_{BST_U} at one end of the first bootstrap capacitor C_{BST_U} is higher than the voltage V_{N1} at the node N1 of the charge pump circuit 360, and V_{BST_U}>V_{CC}−V_{f} is satisfied. At this time, when the voltage drop across the body diode of the transistor MP2 is set to V_{f}, the charge pump voltage V_{CP2} is V_{CP2}=V_{BST_U}−V_{f}.

When the voltage V_{BST_W} at one end of the third bootstrap capacitor C_{BST_W} is lower than the charge pump voltage V_{CP2}, a backward current I_{U} flows through the transistor MP2 of the first current source circuit 270U through the body diode. This current flows as a forward current I_{W} through the transistor MP2 of the third current source circuit 270W. When the backward current I_{U} flows, the first bootstrap capacitor C_{BST_U} is discharged.

As described above, when the current source circuit 270 operates asynchronously with the charge pump circuit 360, in the charging phase, a backward current may flow through a part of the current source circuit 270, and a part of the bootstrap capacitor may be discharged.

On the other hand, when the current source circuit 270 operates in synchronization with the charge pump circuit 360 as in the third embodiment, the current mirror circuit of the current source circuit 270 corresponding to the leg in which the logic is high or Z logic in the charging phase is in the first state (that is, the amount of current is zero). Therefore, the backward flow of the current in the current source circuit 270 is suppressed in the charging phase.

### Fourth Embodiment

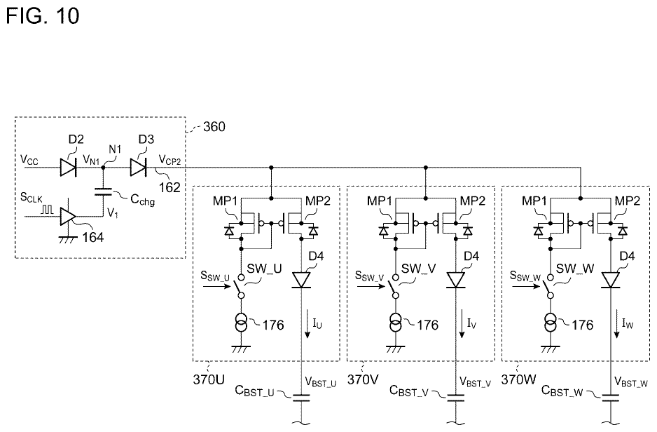

An electronic device according to a fourth embodiment is different from the third embodiment in the configuration and operation of a current source circuit. FIG. 10 is a circuit diagram of a charge pump circuit 360, a first current source circuit 370U, a second current source circuit 370V, and a third current source circuit 370W according to the fourth embodiment. Hereinafter, when the first current source circuit 370U, the second current source circuit 370V, and the third current source circuit 370W are not particularly distinguished, these are also collectively referred to as a “current source circuit 370”.

The first current source circuit 370U according to the fourth embodiment has a configuration in which a rectifying element D4 is added to the first current source circuit 270U according to the third embodiment. The rectifying element D4 according to the present embodiment is a diode. The rectifying element D4 is provided between a transistor MP2 and a first bootstrap capacitor C_{BST_U} such that a direction from the transistor MP2 to the first bootstrap capacitor C_{BST_U} is a forward direction. Specifically, the rectifying element D4 has an anode connected to a drain of the transistor MP2, and a cathode connected to one end of the first bootstrap capacitor C_{BST_U} on the first current source circuit 370U side.

Similarly to the first current source circuit 370U, the second current source circuit 370V also has a configuration in which the rectifying element D4 is added to the second current source circuit 270V according to the third embodiment. Similarly, the third current source circuit 370W has a configuration in which the rectifying element D4 is added to the third current source circuit 270W according to the third embodiment.

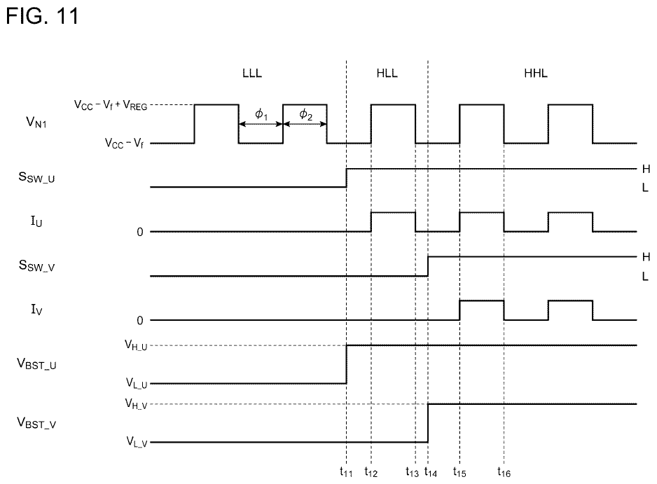

FIG. 11 is a timing chart illustrating an operation example of the charge pump circuit 360 and the current source circuit 370 according to the fourth embodiment. FIG. 11 illustrates the voltage V_{N1} at the node N1 of the charge pump circuit 360, the control signal S_{SW_U} of the first switch SW_U, the current I_{U} output from the first current source circuit 370U, the control signal S_{SW_V} of the second switch SW_V, the current I_{V} output from the second current source circuit 370V, the voltage V_{BST_U} at one end of the first bootstrap capacitor C_{BST_U}, and the voltage V_{BST_V} at one end of the second bootstrap capacitor C_{BST_V} in order from the top.

The logic of the three-phase bridge circuit 282 is “LLL” before time t₁₁. At time t₁₁, it is assumed that each of the voltage across the first bootstrap capacitor C_{BST_U} and the voltage across the second bootstrap capacitor C_{BST_V} is the lower threshold voltage V_{thL}. Further, V_{BST_U} and V_{BST_V} are V_{L_U} and V_{L_V}, respectively. At time t₁₁, the logic of the three-phase bridge circuit 282 changes to “HLL”. As a result, the voltage V_{BST_U} increases from V_{L_U} to V_{H_U}.

The first current source circuit 270U operates to supply a constant current to the first bootstrap capacitor C_{BST_U}, and specifically, supplies the current I_{U} (>0) to the first bootstrap capacitor C_{BST_U} in the boosting phase φ₂ (times t₁₂ to t₁₃). At this time, the control signal S_{SW_U} is maintained high regardless of the phase of the charge pump circuit 360.

At time t₁₄, the logic of the three-phase bridge circuit 282 changes to “HHL”. As a result, the voltage V_{BST_V} increases from V_{L_V} to V_{H_V}. The second current source circuit 270V operates to supply a constant current to the second bootstrap capacitor C_{BST_V}, and specifically, supplies the current I_{V} (>0) to the second bootstrap capacitor C_{BST_V} in the boosting phase φ₂ (times t₁₅ to t₁₆). At this time, the control signal S_{SW_V} is maintained high regardless of the phase of the charge pump circuit 360.

The configurations and operation examples of the charge pump circuit 360 and the current source circuit 370 according to the present embodiment have been described above. The current source circuit 370 according to the present embodiment includes the rectifying element D4. The rectifying element D4 is provided between the transistor MP2 and the bootstrap capacitor such that a direction from the transistor MP to the bootstrap capacitor is a forward direction. Therefore, in the current source circuit 370, the backward flow of the current through the body diode of the transistor MP2 is suppressed.

Although the embodiments according to the present disclosure have been described using specific terms, this description is merely an example for assisting understanding and does not limit the present disclosure or the claims, and the scope of the present disclosure is defined by the claims. Furthermore, not only the embodiments but also embodiments, examples, and modifications not described herein are included in the scope of the present disclosure.

### First Modification

In the above embodiments, an example in which the rectifying element of the bootstrap circuit is the diode has been described. The present disclosure is not limited thereto, and the rectifying element may include, for example, a (P-channel) MOS transistor. The rectifying element includes a MOS transistor, so that synchronous rectification can be performed.

### Second Modification

In the above embodiments, an example in which the switching circuits 10 and 20 include the half-bridge circuit 182 or the three-phase bridge circuit 282 has been described. The present disclosure is not limited thereto, and the switching circuit may include a circuit including various high-side transistors such as an H-bridge circuit. Furthermore, the number of gate driver circuits may be appropriately adjusted according to the number of high-side transistors.

### Third Modification

In the above embodiments, an example in which the high-side transistor includes the N-channel MOS transistor has been described. The present disclosure is not limited thereto, and the high-side transistor may include, for example, an N-channel insulated gate bipolar transistor (IGBT).

### SUPPLEMENTARY NOTE

The technology disclosed in the present specification can be understood as follows in one aspect.

### Item 1

A gate driver circuit for a high-side transistor, including:
a high-side driver structured to drive the high-side transistor;
a charge pump line to which a charge pump voltage higher than an input voltage of the high-side transistor and generated by a charge pump circuit is supplied;
a current source circuit structured to be able to supply a constant current from the charge pump line to a bootstrap capacitor for driving the high-side transistor; and
a current control circuit structured to control on/off of supply of the constant current to the bootstrap capacitor by the current source circuit.

### Item 2

The gate driver circuit according to item 1, further including:
a voltage sensor structured to detect a capacitor voltage of the bootstrap capacitor, wherein
the current control circuit controls on/off of the supply of the constant current to the bootstrap capacitor by the current source circuit according to a comparison result between the capacitor voltage detected by the voltage sensor and a comparison voltage.

### Item 3

The gate driver circuit according to item 2, wherein
the current control circuit maintains the supply of the constant current to the bootstrap capacitor by the current source circuit on until the voltage sensor detects that the capacitor voltage has reached a threshold voltage, and switches the supply of the constant current to the bootstrap capacitor by the current source circuit from on to off in response to the voltage sensor detecting that the capacitor voltage has reached the threshold voltage.

### Item 4

The gate driver circuit according to item 3, wherein
after the capacitor voltage reaches an upper threshold voltage as the threshold voltage, the current control circuit switches the supply of the constant current to the bootstrap capacitor by the current source circuit from off to on in response to the voltage sensor detecting that the capacitor voltage has reduced to a lower threshold voltage lower than the upper threshold voltage.

### Item 5

The gate driver circuit according to any one of items 2 to 4, wherein
the current control circuit switches the supply of the constant current to the bootstrap capacitor by the current source circuit from off to on in response to the voltage sensor detecting that the capacitor voltage is equal to or lower than a predetermined low threshold voltage.

### Item 6

The gate driver circuit according to any one of items 1 to 5, wherein
the current source circuit is structured to be able to switch a magnitude of the constant current.

### Item 7

The gate driver circuit according to any one of items 1 to 6, wherein
the current source circuit includes a current mirror circuit and a switching circuit,
the current mirror circuit includes two transistors forming a current mirror pair, and is structured such that a current flowing through one transistor of the two transistors is copied by the other transistor of the two transistors,
the switching circuit is structured to be able to switch a state of the current mirror circuit between a first state in which a current amount of the one transistor becomes zero and a second state in which a constant current flows through the one transistor, and
the other transistor is provided between the charge pump line and the bootstrap capacitor.

### Item 8

The gate driver circuit according to item 7, wherein
the charge pump circuit includes a charge pump capacitor, and alternately repeats a charging phase for charging the charge pump capacitor and a boosting phase for boosting a voltage at one end on an output side of the charge pump capacitor so as to generate the charge pump voltage, and
the switching circuit operates in synchronization with the charge pump circuit so as to bring the current mirror circuit into the first state in the charging phase and bring the current mirror circuit into the second state in the boosting phase.

### Item 9

The gate driver circuit according to item 7 or 8, wherein
the current source circuit further includes a rectifying element, and
the rectifying element is provided between the other transistor and the bootstrap capacitor such that a direction from the other transistor to the bootstrap capacitor is a forward direction.

### Item 10

A switching circuit including:
the gate driver circuit according to any one of items 1 to 9;
the bootstrap capacitor;
the high-side transistor; and
the charge pump circuit.

### Item 11

A three-phase gate driver that controls a three-phase bridge circuit including a first leg including a first high-side transistor and a first low-side transistor, a second leg including a second high-side transistor and a second low-side transistor, and a third leg including a third high-side transistor and a third low-side transistor, the three-phase gate driver including:
a first gate driver circuit structured to control the first high-side transistor as the high-side transistor, the first gate driver circuit being the gate driver circuit according to any one of items 1 to 9;
a second gate driver circuit structured to control the second high-side transistor as the high-side transistor, the second gate driver circuit being the gate driver circuit according to any one of items 1 to 9; and
a third gate driver circuit structured to control the third high-side transistor as the high-side transistor, the third gate driver circuit being the gate driver circuit according to any one of items 1 to 9.

What is claimed is:

1. A gate driver circuit for a high-side transistor, comprising:
a high-side driver structured to drive the high-side transistor;
a charge pump line to which a charge pump voltage higher than an input voltage of the high-side transistor and generated by a charge pump circuit is supplied;
a current source circuit structured to be able to supply a constant current from the charge pump line to a bootstrap capacitor for driving the high-side transistor; and
a current control circuit structured to control on/off of supply of the constant current to the bootstrap capacitor by the current source circuit.

2. The gate driver circuit according to claim 1, further comprising:
a voltage sensor structured to detect a capacitor voltage of the bootstrap capacitor, wherein
the current control circuit controls on/off of the supply of the constant current to the bootstrap capacitor by the current source circuit according to a comparison result between the capacitor voltage detected by the voltage sensor and a comparison voltage.

3. The gate driver circuit according to claim 2, wherein
the current control circuit maintains the supply of the constant current to the bootstrap capacitor by the current source circuit on until the voltage sensor detects that the capacitor voltage has reached a threshold voltage, and switches the supply of the constant current to the bootstrap capacitor by the current source circuit from on to off in response to the voltage sensor detecting that the capacitor voltage has reached the threshold voltage.

4. The gate driver circuit according to claim 3, wherein
after the capacitor voltage reaches an upper threshold voltage as the threshold voltage, the current control circuit switches the supply of the constant current to the bootstrap capacitor by the current source circuit from off to on in response to the voltage sensor detecting that the capacitor voltage has reduced to a lower threshold voltage lower than the upper threshold voltage.

5. The gate driver circuit according to claim 2, wherein
the current control circuit switches the supply of the constant current to the bootstrap capacitor by the current source circuit from off to on in response to the voltage sensor detecting that the capacitor voltage is equal to or lower than a predetermined low threshold voltage.

6. The gate driver circuit according to claim 1, wherein
the current source circuit is structured to be able to switch a magnitude of the constant current.

7. The gate driver circuit according to claim 1, wherein
the current source circuit includes a current mirror circuit and a switching circuit,
the current mirror circuit includes two transistors forming a current mirror pair, and is structured such that a current flowing through one transistor of the two transistors is copied by the other transistor of the two transistors,
the switching circuit is structured to be able to switch a state of the current mirror circuit between a first state in which a current amount of the one transistor becomes zero and a second state in which a constant current flows through the one transistor, and
the other transistor is provided between the charge pump line and the bootstrap capacitor.

8. The gate driver circuit according to claim 7, wherein
the charge pump circuit includes a charge pump capacitor, and alternately repeats a charging phase for charging the charge pump capacitor and a boosting phase for boosting a voltage at one end on an output side of the charge pump capacitor so as to generate the charge pump voltage, and
the switching circuit operates in synchronization with the charge pump circuit so as to bring the current mirror circuit into the first state in the charging phase and bring the current mirror circuit into the second state in the boosting phase.

9. The gate driver circuit according to claim 7, wherein
the current source circuit further includes a rectifying element, and
the rectifying element is provided between the other transistor and the bootstrap capacitor such that a direction from the other transistor to the bootstrap capacitor is a forward direction.

10. A switching circuit comprising:
the gate driver circuit according to claim 1;
the bootstrap capacitor;
the high-side transistor; and
the charge pump circuit.

11. A three-phase gate driver that controls a three-phase bridge circuit including a first leg including a first high-side transistor and a first low-side transistor, a second leg including a second high-side transistor and a second low-side transistor, and a third leg including a third high-side transistor and a third low-side transistor, the three-phase gate driver comprising according to claim 1:
a first gate driver circuit structured to control the first high-side transistor as the high-side transistor, the first gate driver circuit being the gate driver circuit;
a second gate driver circuit structured to control the second high-side transistor as the high-side transistor, the second gate driver circuit being the gate driver circuit; and
a third gate driver circuit structured to control the third high-side transistor as the high-side transistor, the third gate driver circuit being the gate driver circuit.
